(19) United States
(12) Patent Application Publication
(10) Pub. No.: US 2022/0123086 A1
(43) Pub. Date: Apr. 21, 2022

(54) DISPLAY PANEL

(71) Applicant: SHENZHEN CHINA STAR OPTOELECTRONICS SEMICONDUCTRO DISPLAY TECHNOLOGY CO., LTD., Shenzhen (CN)

(72) Inventors: Zhida XU, Shenzhen (CN); Ilgon KIM, Shenzhen (CN); Bin ZHAO, Shenzhen (CN); Xin ZHANG, Shenzhen (CN); Jun ZHAO, Shenzhen (CN)

(73) Assignee: SHENZHEN CHINA STAR OPTOELECTRONICS SEMICONDUCTRO DISPLAY TECHNOLOGY CO., LTD., Shenzhen (CN)

(21) Appl. No.: 16/767,174

(22) PCT Filed: Apr. 22, 2020
(86) PCT No.: PCT/CN2020/086131

§ 371 Date: May 27, 2020

(30) Foreign Application Priority Data
Mar. 22, 2020 (CN) 202010204814.2

(51) Int. Cl. H01L 27/32

(52) U.S. Cl. CPC H01L 27/3276

(57) ABSTRACT

The present application discloses a display panel, which includes a signal line group, a driving module, and connecting lines located in a layer different from the signal line group, wherein each of the first signal lines in the signal line group includes a first branch arranged along a first direction, all the first branches are arranged parallel to and spaced apart from each other, the first branches of all the first signal lines are electrically connected to a node portion, the connecting lines are disposed along a second direction, each of the first signal lines includes an overlapping portion overlapping the connecting lines, and the node portion includes the overlapping portion.

### BACKGROUND OF INVENTION

### Field of Invention

The present application relates to a field of display technology, in particular to a display panel.

### Description of Prior Art

In display products of high-resolution such as 8K, multiple clock signal lines are usually provided to share in-plane signal transmission, and a display panel is provided with the clock signal lines arranged in different layers and metal wires arranged in directions different from the clock signal lines, wherein some metal wires overlap the clock signal wires at an area where the metal wires correspond to the clock signal wires. Meanwhile, since clock signals in the display products of high-resolution such as 8K have a greater voltage difference, there is a greater risk of electrostatic damage between the clock signal lines and the metal lines.

In existing display products of high-resolution such as 8K, some metal wires overlap the clock signal wires at an area where the metal wires correspond to the clock signal wires, and there is a greater risk of electrostatic damage between the clock signal lines and the metal lines.

### SUMMARY OF INVENTION

In a first aspect, the present application provides a display panel, including a signal line group, a driving module, and connecting lines located in a layer different from the signal line group,

wherein the signal line group includes at least two first signal lines, each of the first signal lines includes a first branch arranged along a first direction, all the first branches are arranged parallel to and spaced apart from each other, the first branches of all the first signal lines are electrically connected to a node portion, the connecting lines are disposed along a second direction, one end of each of the connecting lines is electrically connected to the driving module, another end of each of the connecting lines is electrically connected to the signal line group, each of the first signal lines includes an overlapping portion overlapping the connecting lines, and the node portion includes the overlapping portion.

In some embodiments, the connecting lines are arranged at intervals in the first direction, and each of the connecting lines is correspondingly electrically connected to one signal line in the signal line group.

In some embodiments, the driving module is disposed at a side of the signal line group along the second direction, and the signal line group further includes a second signal line spaced apart by a maximum distance from the driving module, and the second signal line is spaced apart from the first signal lines.

In some embodiments, a maximum distance between two of the connecting lines is smaller than a length of the node portion in the first direction.

In some embodiments, each of electrical connection points of the first signal lines and the connecting lines is located at the node portion.

In some embodiments, each of the first signal lines further includes a second branch disposed along the first direction, and the first branch and the second branch are located respectively on opposite sides of the node portion.

In some embodiments, both the first branch and second branch of part of the first signal lines are electrically connected to the node potion through a bent portion, and an angle formed between the bent portion and the first branch and an angle formed between the bent portion and the second branch are both greater than 90 degrees.

In some embodiments, at least part of the first signal lines are located on a first side of the node portion or/and at least part of the first signal lines are located on a second side of the node portion opposite to the first side.

In some embodiments, the first branch and the second branch of one of the first signal lines are on a straight line same as the node portion.

In some embodiments, the first signal lines include a clock signal line.

In some embodiments, the driving module includes a gate driver on array (GOA) driving module, and the GOA driving module includes GOA driving units electrically connected in one-to-one correspondence to the connecting lines.

In some embodiments, the first direction and the second direction are perpendicular to each other.

In a second aspect, the present application further provides a display panel, including a signal line group, a driving module, and connecting lines located in a layer different from the signal line group,

wherein, the signal line group includes at least two first signal lines, each of the first signal lines includes a first branch arranged along a first direction, all the first branches are arranged parallel to and spaced apart from each other, the first branches of all the first signal lines are electrically connected to a node portion, the connecting lines are disposed along a second direction, one end of each of the connecting lines is electrically connected to the driving module, another end of each of the connecting lines is electrically connected to the signal line group, each of the first signal lines includes an overlapping portion overlapping the connecting lines, and the node portion includes the overlapping portion.

In some embodiments, the connecting lines are arranged at intervals in the first direction, and each of the connecting lines is correspondingly electrically connected to one signal line in the signal line group.

In some embodiments, the driving module is disposed at a side of the signal line group along the second direction, and the signal line group further includes a second signal line spaced apart by a maximum distance from the driving module, and the second signal line is spaced apart from the first signal lines.

In some embodiments, a maximum distance between two of the connecting lines is smaller than a length of the node portion in the first direction.

In some embodiments, each of electrical connection points of the first signal lines and the connecting lines is located at the node portion.

In some embodiments, each of the first signal lines further includes a second branch disposed along the first direction, the first branch and the second branch are located respectively on opposite sides of the node portion.

In some embodiments, both the first branch and second branch of part of the first signal lines are electrically connected to the node potion through a bent portion, and an angle formed between the bent portion and the first branch and an angle formed between the bent portion and the second branch are both greater than 90 degrees.

In some embodiments, at least part of the first signal lines are located on a first side of the node portion or/and at least part of the first signal lines are located on a second side of the node portion opposite to the first side.

By electrically connecting the first signal lines overlapping the connecting lines to the node portion, and concentrating all the overlapping portions between the connecting lines and the first signal lines at the node portion, the overlapping sites between the connecting lines and the first signal lines are reduced, and thus the risk of electrostatic damage between the connecting lines and the first signal lines is reduced.

### BRIEF DESCRIPTION OF DRAWINGS

The technical solutions and other beneficial effects of the present application will be apparent through the detailed description of the specific implementation of the present application in conjunction with the accompanying drawings.

FIG. 1 is a schematic structural diagram of a display panel according to an embodiment of the invention.

FIG. 2 is a schematic diagram of a first structure of a display panel according to Embodiment 1 of the present invention.

FIG. 3 is a schematic cross-sectional structure diagram of a display panel along a section line A-A in FIG. 2 according to Embodiment 1 of the present invention.

FIG. 4 is a schematic diagram of a second structure of a display panel according to Embodiment 1 of the present invention.

FIG. 5 is a schematic diagram of a third structure of a display panel according to Embodiment 1 of the present invention.

FIG. 6 is a schematic diagram of a fourth structure of a display panel according to Embodiment 1 of the present invention.

FIG. 7 is a schematic diagram of a fifth structure of a display panel according to Embodiment 1 of the present invention.

FIG. 8 is a schematic diagram of a first structure of a display panel according to Embodiment 2 of the present invention.

FIG. 9 is a schematic structural diagram of a second structure of a display panel according to Embodiment 2 of the present invention.

Elements in the drawings are designated by reference numerals listed below:

10. signal line group; 11, first signal line; 111, first branch; 112, second branch; 113, bent portion; 12, second signal line; 13, node portion; 14, 1st first signal line; 15, 2nd first signal line; 16, 3rd first signal line; 20, connecting line; 30, driving module; 31, GOA driving unit; 32, first-stage GOA driving unit; 33, second-stage GOA driving unit; 34, third-stage GOA driving unit; 40, substrate; 50, display area; 60, wiring area; 70, insulating film layer; 80, auxiliary line; 90, balance line.

### DETAILED DESCRIPTION OF PREFERRED EMBODIMENTS

The following description of the various embodiments is provided to illustrate the specific embodiments of the invention. Directional terms mentioned in the present invention, such as “vertical”, “horizontal”, “upper”, “bottom”, “pre”, “post”, “left”, “right”, “inside”, “outside”, “side”, etc., only refer to the direction of the additional drawing. Therefore, the directional terminology used is for the purpose of illustration and understanding of the invention. In the figures, structurally similar elements are denoted by the same reference numerals.

The present invention is directed to above the technical problem in existing display products of high-resolution such as 8K that some metal wires overlap the clock signal wires at an area where the metal wires correspond to the clock signal wires, and there is a greater risk of electrostatic damage between the clock signal lines and the metal lines.

### Embodiment 1

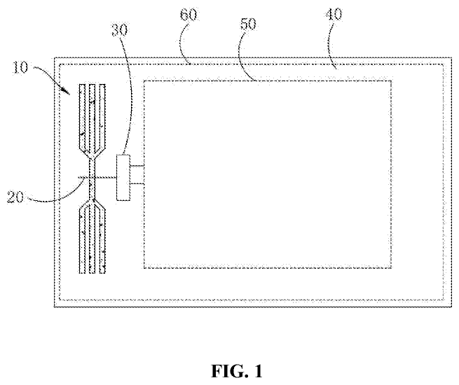

A display panel, as shown in FIG. 1, the display panel includes a substrate 40, a signal line group 10 disposed on the substrate 40, a driving module 30, and connecting lines located in a layer different from the signal line group 20.

The display panel has a display area 50 and a wiring area 60 disposed around at least one side of the display area 50, and the signal line group 10, the driving module 30, and the connecting lines 20 are all located in the wiring area 60 for transmitting driving signals to a display unit located in the display area 50.

It should be noted that FIG. 1 only illustrates that the signal line group 10, the driving module 30, and the connecting lines 20 are provided on one side of the display panel, but in actual implementation, the signal line group 10, the driving module 30, and the connecting lines 20 may also be provided on multiple sides of the display panel.

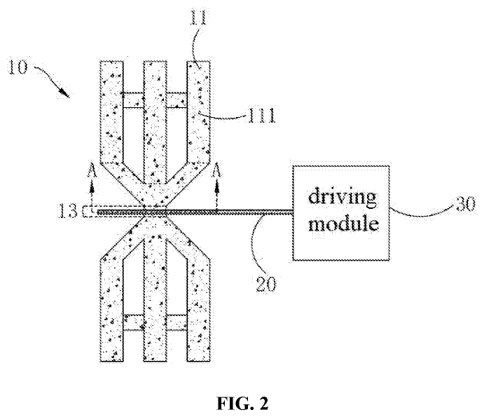

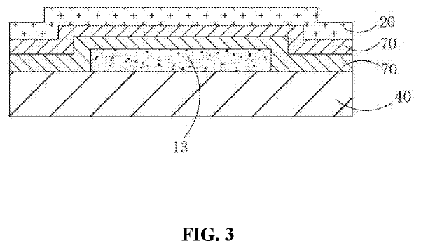

As shown in FIGS. 2 and 3, the signal line group 10 and the connecting lines 20 are both disposed above a first side of the substrate 40, and the connecting lines 20 are located on a side of the signal line group 10 away from the substrate 40.

It should be noted that the signal lines in the signal line group 10 can be used to transmit signals, one end of each of the connecting lines 20 is electrically connected to the driving module, another end of each of the connecting lines 20 is electrically connected to the signal line group 10, so as to transmit the driving signal output by the signal line group 10 to the driving module 30.

An insulating film layer 70 covering the signal line group 10 is further provided between the connecting lines 20 and the signal line group 10. The insulating film layer 70 may be a single-layered or multi-layered structure. The connecting lines 20 may be electrically connected to the node portion 13 through a via hole penetrating through the insulating film layer 70.

Specifically, the signal line group 10 includes at least two first signal lines 11, each of the first signal lines 11 includes a first branch 111 disposed along a first direction, and all the first branches 111

are arranged parallel to and spaced apart from each other, the first branches 111 of all the first signal lines 11 are electrically connected to a node portion 13, the connecting lines 20 are disposed along a second direction, each of the first signal lines 44 includes an overlapping portion overlapping the connecting lines 20, and the node portion 13 includes the overlapping portion.

It should be noted that the overlapping portion of the first signal lines 11 and the connecting lines 20 refers to a portion where an orthographic projection of the connecting lines 20 on a plane where the first signal lines 11 are located overlaps the first signal lines 11. By electrically connecting the first signal lines 11 overlapping the connecting lines 20 to the node portion 13, and concentrating all the overlapping portions between the connecting lines 20 and the first signal lines 11 at the node portion 13, the overlapping site between the connecting lines 20 and the first signal lines 11 are reduced, and thus the risk of electrostatic damage between the connecting lines 20 and the first signal lines 11 is reduced.

It should be noted that the first direction may be perpendicular to the second direction. In actual implementation, the first direction may also not be perpendicular to the second direction according to the in-plane space and layout.

In one embodiment, the driving module 30 is disposed on the side of the signal line group 10 along the second direction.

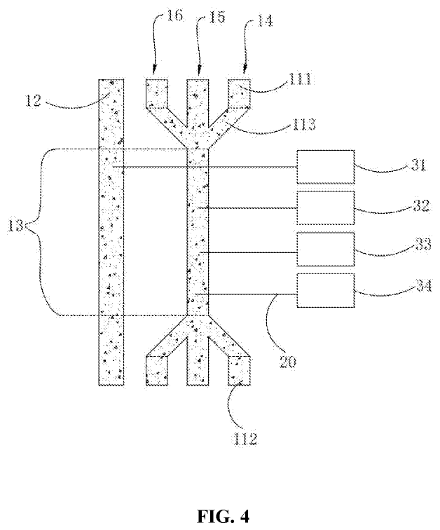

Specifically, as shown in FIG. 4, a plurality of the connecting lines 20 are arranged at intervals in the first direction, and each of the connecting lines 20 corresponds to and is electrically connected to one of the signal lines in the signal line group 10. Same or different signals are transmitted to the driving module 30 through a plurality of the signal lines in a time-sharing or segmented manner, and the in-plane load of the display panel during signal transmission is shared by a plurality of the multiple signal lines.

The first signal lines 11 include a clock signal line, the driving module 30 includes a GOA driving module, and the GOA driving module includes GOA driving units 31 electrically connected to the connecting lines 20 in a one-to-one correspondence.

In this embodiment, the GOA driving units 31 at all stages in the GOA driving module input signals to the display panel in a stage cascade way.

Specifically, referring to FIG. 4, the first signal lines 14 in the signal line group 10 are correspondingly connected to the first-stage GOA driving unit 32, the 2nd one of the first signal lines 15 is correspondingly connected to the second-stage GOA driving unit 33, and the 3rd one of the first signal lines 16 is correspondingly connected to the third-stage GOA driving unit 34. When the display panel displaying, and the first signal transmitted by the 1st one 14 of the first signal lines is received by the first-stage GOA driving unit 32 at the node portion 13. After the transmission of the first signal is completed, the second signal transmitted by the 2nd one 15 of the first signal lines is received by the second-stage GOA driving unit 33 at the node portion 13, and after the second signal transmission is completed, the third signal transmitted by the 3rd one 16 of the first signal lines is received by the third-stage GOA driving unit 34 at the node portion 13, and so on. In this embodiment, by connecting the plurality of first signal lines 11 of the signal line group through the node portion 13, and sequentially transmitting signals by the plurality of signal lines 11 to the display panel in a stage cascade way, crosstalk between the signals can be avoided, thereby saving the manufacturing process.

Specifically, the signal line group 10 further includes a second signal line 12 spaced apart by a maximum distance from the driving module 10, and the second signal line 12 is spaced apart from the first signal lines 11.

It should be noted that, in all the signal lines of the signal line group 10, the distance between the second signal line 12 and the driving module 30 is the largest. At this time, the connecting lines 20 connected to the second signal line 12 can be electrically connected to the second signal line 12 without crossing the second signal line 12, so the second signal line 12 does not need to be electrically connected to the node portion 13 to reduce the load at the node portion 13.

Specifically, a maximum distance between two of the connecting lines 20 is smaller than a length of the node portion 13 in the first direction, so as to ensure that all the overlapping portions of the connecting lines 20 and the first signal lines 11 fall within the node portion 13, such that the overlapping sites between the connecting lines 20 and the first signal lines 11 are reduced, and thus the risk of electrostatic damage is reduced.

The electrical connection points of the first signal lines 11 and the connecting lines 20 are all located at the node portion 13, and the connecting lines 20 may be electrically connected to the node portion 13 through a via hole penetrating through the insulating film layer 70.

Specifically, each of the first signal lines 11 further includes a second branch 112 disposed along the first direction, and the first branch 111 and the second branch 112 are respectively located on opposite sides of the node portion 13.

It should be noted that the first branch 111 and the second branch 112 are located on opposite sides of the node portion 13 along the first direction, referring to FIG. 3, that is, the first branch 111 and the second branch 112 are located on an upper side and a lower side of the node portion 13, respectively.

Both the first branch 111 and second branch 112 of part of the first signal lines 11 are electrically connected to the node potion 13 through a bent portion 113, and an angle formed between the bent portion 113 and the first branch 111 and an angle formed between the bent portion 113 and the second branch 112 are both greater than 90 degrees.

It should be noted that the first branch 111 and the second branch 112 are electrically connected to the node portion 13 through the bent portion 113, so as to ensure sufficient spacing between adjacent ones of the first branches 111 and between adjacent ones of the second branches without increasing a width of the node portion 13, thus saving wiring space.

Specifically, at least part of the first signal lines 11 are located on a first side of the node portion 13 or/and at least part of the first signal lines 11 are located on a second side of the node portion 13 opposite to the first side.

It should be noted that the first side and the second side of the node portion 13 are the opposite sides of the node portion 13 along the second direction.

In one embodiment, as shown in FIGS. 4 to 6, the first branch 111 and the second branch 112 of one of the first signal lines 11 are on a straight line same as the node portion 13.

It should be noted that in all the first signal lines 11, one of the first signal lines 11 may be selected as a carrier signal line, and the first branch 111 and the second branch 112 of the carrier signal line and the node portion 13 are arranged along a straight line and can be integrally formed. All the first signal lines 11 located on opposite sides of the carrier signal line are electrically connected to the node portion 13 through a bent portion 113 provided near the carrier signal line.

It should be noted that, referring to FIG. 4, the first signal lines 11 at the center area of the signal line group 10 may be selected as the carrier signal line, to facilitate the first signal lines 11 on opposite sides of the carrier signal line to be electrically connected to the node portion 13. Of course, the first signal lines 11 can also be selected as the carrier signal line according to the actual situation.

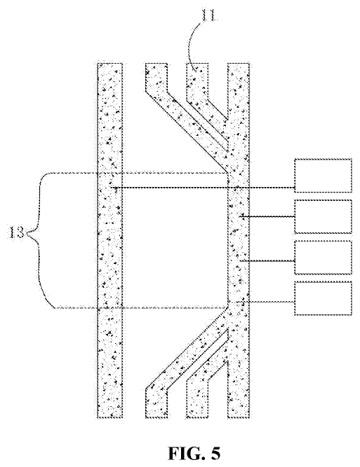

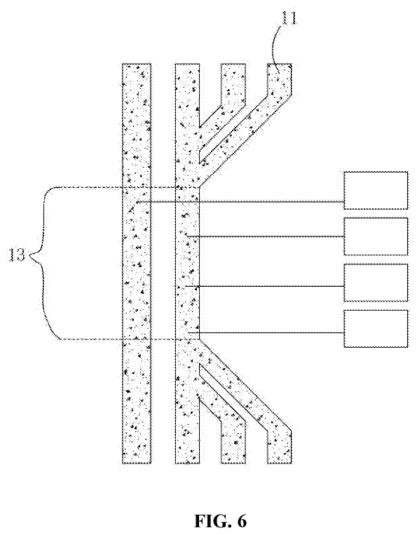

It should be noted that, referring to FIG. 5 and FIG. 6, the first signal lines 11 located on the side of the signal line group 10 may also be selected as the carrier signal line. All the other first signal lines 11 are electrically connected to the node portion 13 through the bent portion 113 provided near the carrier signal line.

In actual implementation, the first signal lines 11 in the signal line group 10 closest to the driving module 30 may be selected as the carrier signal line. At this time, the distance between the node portion 13 and the driving module 30 is short, and the length of the connecting lines 20 is shortened to reduce impedance and load of the connecting lines 20.

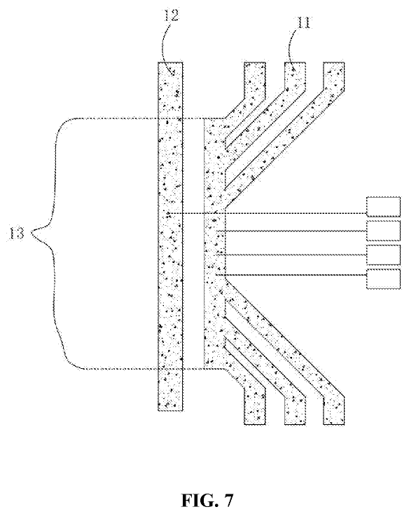

In another embodiment, as shown in FIG. 7, it is also possible not to select the carrier signal line, but to electrically connect all the first signal lines 11 to the separately provided node portion 13 through the bent portion 113.

It should be noted that FIG. 7 only illustrates that the node portion 13 is disposed on one side of the first signal lines 11 close to the second signal line 12. However, in actual implementation, the node portion 13 may also be disposed on one side of the first signal lines 11 away from the second signal line 12, or the node portion 13 may also be disposed at the central area of the signal line group 10.

### Embodiment 2

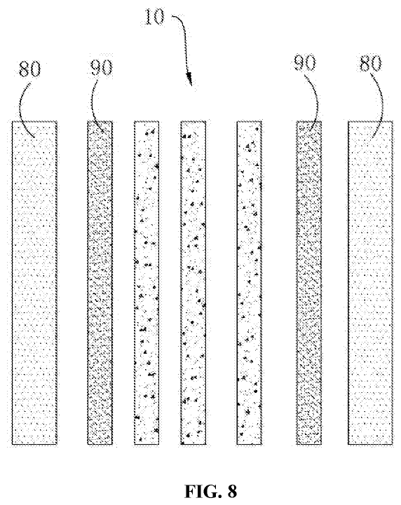

A display panel, as shown in FIG. 8, the different from Embodiment 1 is in that the display panel further includes auxiliary lines 80 provided on the left and right sides of the signal line group 10, wherein the auxiliary lines 80 are disposed along the first direction and receiving a low frequency signal or a DC signal for sharing signal transmission.

A balance line 90 is further provided between the auxiliary lines 80 and the signal line group 10, wherein an input end of the balance line 90 receives a high-frequency signal, and an output end of the balance line 90 is grounded or electrically connected to a reference voltage line.

It should be noted that, for those skilled in the art, due to the existence of the auxiliary lines 80, the lateral coupling effects of the signal lines in the signal line group 10 at different distances from the auxiliary lines 80 are not completely consistent, which is likely to cause inconsistent load of the signal lines, impacting the quality of the product. In addition, by setting the balance line 90 between the signal line group 10 and the auxiliary lines 80, and the balance line 90 receives a high-frequency signal, such that the lateral capacitive coupling of the signal lines near the outside is the same as the lateral capacitive coupling of the signal lines in the center area, to balance the coupling effect between each of the signal lines in the signal line group 10 and the auxiliary lines 80, so as to balance the load of each of the signal lines.

A frequency amplitude of the signal received by the balance line 90 is the same as a frequency amplitude of the signal received by the signal line, the balance line 90 and the signal lines may be made of a same material, and the balance line 90 and the signal line may have a same width.

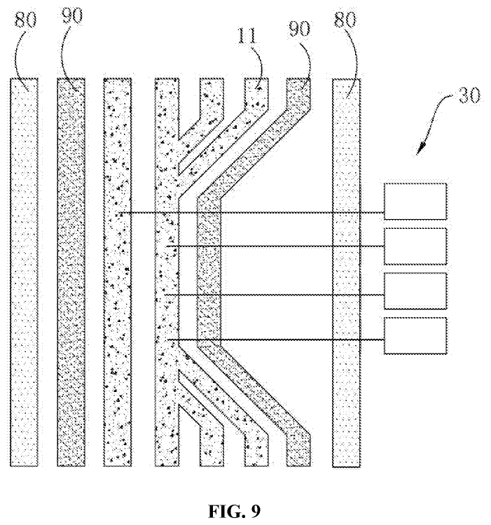

In an embodiment, as shown in FIG. 9, a shape of the first balance line 90 between the signal line group 10 and the driving module 30 is the same as a shape of each of the first signal lines 11 disposed near the driving module 30, and the size of the first balance line 90 is the same as the size of each of the first signal lines 11, such that a better capacitive coupling effect is achieved.

The beneficial effect of the present invention is that by electrically connecting the first signal lines 11 overlapping the connecting lines 20 to the node portion 13, and concentrating all the overlapping portions between the connecting lines 20 and the first signal lines 11 at the node portion 13, the overlapping sites between the connecting lines 20 and the first signal lines 11 are reduced, and thus the risk of electrostatic damage between the connecting lines 20 and the first signal lines 11 is reduced.

In the above embodiments, the descriptions of each embodiment have their own emphasis. The parts that are not described in detail in an embodiment can be referred to the detailed descriptions in other embodiments above, which will not be repeated herein for brevity.

The light-emitting electrochemical cell and the electroluminescence display device provided in the embodiments of the present application have been described in detail above. Specific examples are used in this document to explain the principles and implementation of the present invention. The descriptions of the above embodiments are only for understanding the method of the present invention and its core ideas, to help understand the technical solution of the present application and its core ideas, and a person of ordinary skill in the art should understand that it can still modify the technical solution described in the foregoing embodiments, or equivalently replace some of the technical features. Such modifications or replacements do not depart the spirit of the corresponding technical solutions beyond the scope of the technical solutions of the embodiments of the present application.

What is claimed is:

1. A display panel, comprising a signal line group, a driving module, and connecting lines located in a layer different from the signal line group,
wherein the signal line group comprises at least two first signal lines, each of the first signal lines comprises a first branch arranged along a first direction, all the first branches are arranged parallel to and spaced apart from each other, the first branches of all the first signal lines are electrically connected to a node portion, the connecting lines are disposed along a second direction, one end of each of the connecting lines is electrically connected to the driving module, another end of each of the connecting lines is electrically connected to the signal line group, each of the first signal lines comprises an overlapping portion overlapping the connecting lines, and the node portion comprises the overlapping portion.

2. The display panel according to claim 1, wherein the connecting lines are arranged at intervals in the first direction, and each of the connecting lines is correspondingly electrically connected to one signal line in the signal line group.

3. The display panel according to claim 2, wherein the driving module is disposed at a side of the signal line group along the second direction, and the signal line group further comprises a second signal line spaced apart by a maximum distance from the driving module, and the second signal line is spaced apart from the first signal lines.

4. The display panel according to claim 2, wherein a maximum distance between two of the connecting lines is smaller than a length of the node portion in the first direction.

5. The display panel according to claim 4, wherein each of electrical connection points of the first signal lines and the connecting lines is located at the node portion.

6. The display panel according to claim 1, wherein each of the first signal lines further comprises a second branch disposed along the first direction, and the first branch and the second branch are located respectively on opposite sides of the node portion.

7. The display panel according to claim 6, wherein both the first branch and second branch of part of the first signal lines are electrically connected to the node potion through a bent portion, and an angle formed between the bent portion and the first branch and an angle formed between the bent portion and the second branch are both greater than 90 degrees.

8. The display panel according to claim 6, wherein at least part of the first signal lines are located on a first side of the node portion or/and at least part of the first signal lines are located on a second side of the node portion opposite to the first side.

9. The display panel according to claim 8, wherein the first branch and the second branch of one of the first signal lines are on a straight line same as the node portion.

10. The display panel according to claim 3, wherein the first signal lines comprise a clock signal line.

11. The display panel according to claim 2, wherein the driving module comprises a gate driver on array (GOA) driving module, and the GOA driving module comprises GOA driving units electrically connected in one-to-one correspondence to the connecting lines.

12. The display panel according to claim 1, wherein the first direction and the second direction are perpendicular to each other.

13. A display panel, comprising a signal line group, a driving module, and connecting lines located in a layer different from the signal line group,
wherein, the signal line group comprises at least two first signal lines, each of the first signal lines comprises a first branch arranged along a first direction, all the first branches are arranged parallel to and spaced apart from each other, the first branches of all the first signal lines are electrically connected to a node portion, the connecting lines are disposed along a second direction, one end of each of the connecting lines is electrically connected to the driving module, another end of each of the connecting lines is electrically connected to the signal line group, each of the first signal lines comprises an overlapping portion overlapping the connecting lines, and the node portion comprises the overlapping portion.

14. The display panel according to claim 13, wherein the connecting lines are arranged at intervals in the first direction, and each of the connecting lines is correspondingly electrically connected to one signal line in the signal line group.

15. The display panel according to claim 14, wherein the driving module is disposed at a side of the signal line group along the second direction, and the signal line group further comprises a second signal line spaced apart by a maximum distance from the driving module, and the second signal line is spaced apart from the first signal lines.

16. The display panel according to claim 14, wherein a maximum distance between two of the connecting lines is smaller than a length of the node portion in the first direction.

17. The display panel according to claim 16, wherein each of electrical connection points of the first signal lines and the connecting lines is located at the node portion.

18. The display panel according to claim 13, wherein each of the first signal lines further comprises a second branch disposed along the first direction, the first branch and the second branch are located respectively on opposite sides of the node portion.

19. The display panel according to claim 18, wherein both the first branch and second branch of part of the first signal lines are electrically connected to the node potion through a bent portion, and an angle formed between the bent portion and the first branch and an angle formed between the bent portion and the second branch are both greater than 90 degrees.

20. The display panel according to claim 18, wherein at least part of the first signal lines are located on a first side of the node portion or/and at least part of the first signal lines are located on a second side of the node portion opposite to the first side.
